(19) United States
(12) Patent Application Publication
(10) Pub. No.: US 2018/0011714 A1
(43) Pub. Date: Jan. 11, 2018

(54) GRACEFUL SHUTDOWN WITH ASYNCHRONOUS DRAM REFRESH OF NON-VOLATILE DUAL IN-LINE MEMORY MODULE

(71) Applicant: SUPER MICRO COMPUTER, INC., San Jose, CA (US)

(72) Inventors: Donald HAN, San Jose, CA (US); Rsong-Hsiang SHIAO, San Jose, CA (US); Liang XU, San Jose, CA (US)

(73) Assignee: SUPER MICRO COMPUTER, INC., San Jose, CA (US)

(21) Appl. No.: 15/261,397

(22) Filed: Sep. 9, 2016

Related U.S. Application Data
(60) Provisional application No. 62/359,934, filed on Jul. 8, 2016.

(51) Int. Cl. G06F 9/44; G06F 3/06; G11C 11/406; G06F 1/28

(52) U.S. Cl. CPC G06F 9/442; G11C 11/406; G06F 3/0685; G06F 3/0659; G06F 3/0634; G06F 3/0604; G06F 1/28

(57) ABSTRACT

A graceful shutdown of a computer system is initiated by sending a command to an asynchronous dynamic random access memory refresh (ADR) trigger device to assert an ADR trigger. Responsive to the command, the ADR trigger device asserts the ADR trigger to initiate an ADR of a non-volatile dual in-line memory module (NVDIMM) of the computer system. In response to the ADR trigger being asserted by the ADR trigger device, an ADR of the NVDIMM is performed before completing the graceful shutdown of the computer.

### CROSS-REFERENCE TO RELATED APPLICATION

This application claims the benefit of U.S. Provisional Application No. 62/359,934, filed Jul. 8, 2016, which is incorporated herein by reference in its entirety.

### BACKGROUND OF THE INVENTION

### 1. Field of the Invention

The present invention relates generally to computer systems.

### 2. Description of the Background Art

A computer system may include one or more central processing units and one or more memory modules. A memory module comprises one or more memory integrated circuits (“chips”). A memory chip may comprise volatile memory (e.g., dynamic random access memory (DRAM)), non-volatile memory (e.g., flash memory), or both. Volatile memory loses its contents when the computer system's power is interrupted. In contrast, non-volatile memory keeps its contents even in the absence of system power. Generally speaking, volatile memory is faster than non-volatile memory and is thus preferred as main memory for processes of the operating system, application programs, etc. Currently-available computer systems typically employ dual in-line memory modules (DIMMs), which comprise volatile memory, for main memory.

Unlike a DIMM, a non-volatile DIMM (NVDIMM) comprises both volatile memory to provide fast access speeds and non-volatile memory as insurance against power failure. More particularly, in an NVDIMM, the contents of the volatile memory is stored in the non-volatile memory in an asynchronous DRAM refresh (ADR) cycle in the event of a power failure but not when the system is gracefully shut down.

### SUMMARY

In one embodiment, a graceful shutdown of a computer system is initiated by sending a command to an asynchronous dynamic random access memory refresh (ADR) trigger device to assert an ADR trigger. Responsive to the command, the ADR trigger device asserts the ADR trigger to initiate an ADR of a non-volatile dual in-line memory module (NVDIMM) of the computer system. In response to the ADR trigger being asserted by the ADR trigger device, an ADR of the NVDIMM is performed before completing the graceful shutdown of the computer. The ADR trigger device may be a baseboard management controller (BMC) or an original equipment manufacturer (OEM) logic device. The ADR trigger may be activation of a power button. For example, the BMC or OEM logic device may assert a power button signal on a power button pin of a peripheral controller hub (PCH) to initiate the ADR. The BMC or OEM logic device may assert the power button signal in response to receiving an OEM command.

These and other features of the present invention will be readily apparent to persons of ordinary skill in the art upon reading the entirety of this disclosure, which includes the accompanying drawings and claims.

### DESCRIPTION OF THE DRAWINGS

FIG. 1 shows a schematic diagram of a computer system in accordance with an embodiment of the present invention.

FIG. 2 shows a flow diagram of a method of performing a graceful shutdown of a computer system in accordance with an embodiment of the present invention.

The use of the same reference label in different drawings indicates the same or like components.

### DETAILED DESCRIPTION

In the present disclosure, numerous specific details are provided, such as examples of systems, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

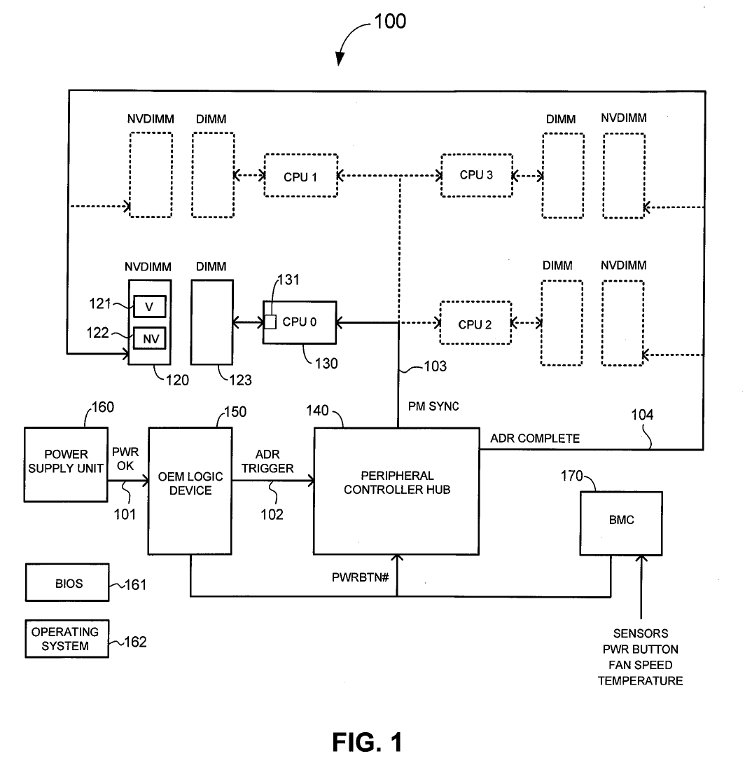

FIG. 1 shows a schematic diagram of a computer system 100 in accordance with an embodiment of the present invention. The computer system 100 may be implemented using components that are commercially-available from the INTEL Corporation, for example. More specifically, in the example of FIG. 1, a central processing unit (CPU) 130, a peripheral controller hub (PCH) 140, and a baseboard management controller (BMC) 170 may comprise devices that conform to the HASWELL processor microarchitecture of the INTEL Corporation. As can be appreciated, embodiments of the present invention may also be implemented using compatible or similar devices from other computer chip vendors.

In the example of FIG. 1, the computer system 100 may have one or more CPUs 130. Only one CPU 130 is described for clarity of illustration. The CPU 130 may have an integrated memory controller 131 for controlling one or more DIMMs 123 and one or more NVDIMMs 120. A DIMM 123 has volatile memory only, whereas an NVDIMM 120 has a volatile memory 121 and a non-volatile memory 122.

An original equipment manufacturer (OEM), such as the SUPER MICRO COMPUTER, INC. of San Jose, Calif., employs components from computer chip vendors to design and manufacture a computer system. The OEM may design-in additional functionality that may be unique to the OEM or its customers. In the example of FIG. 1, the computer system 100 includes an OEM logic device 150, which may comprise a complex programmable logic device (CPLD), field programmable gate array (FPGA), application specific integrated circuit (ASIC), or other programmable logic or custom logic device. As its name implies, the OEM logic device 150 is unique to the OEM of the computer system 100, and allows the OEM to implement certain features that are not necessarily provided by the computer chip vendor. As will be more apparent below, the OEM logic device 150 may be employed as a graceful shutdown ADR trigger device for initiating an ADR of the NVDIMM 120 in the event of a graceful shutdown of the computer system 100.

The PCH 140 is configured to provide peripheral device (e.g., keyboard, mouse, display, disk) interface for the CPU 130. In one embodiment, the PCH 140 comprises an INTEL PCH chip.

The BMC 170 is configured to monitor sensor signals indicative of the environmental condition of the computer system 100 (e.g., fan speed, temperature) and to receive external inputs (e.g., power button, serial port). In one embodiment, the BMC 170 comprises an INTEL BMC chip. In the example of FIG. 1, both the BMC 170 and the OEM logic device 150 may generate a power button signal on the power button pin (PWRBTN#) of the PCH 140. In normal use, asserting the power button signal indicates that the power button of the computer system 100 has been activated by the user, i.e., pressed by the user. In embodiments of the present invention, either the BMC 170 or the OEM logic device 150 may be employed as a graceful shutdown ADR trigger device for initiating ADR when an OEM command to do so is received by either the BMC 170 or the OEM logic device 150. In response to receiving the OEM command, the BMC 170 or the OEM logic device 150 may assert the power button signal on the PCH PWRBTN# pin to simulate power button activation and thereby trigger the ADR of the NVDIMM 120.

The computer system 100 includes a basic input/output system (BIOS) 161. The BIOS 161, also referred to as “system firmware,” may include code (i.e., computer instructions) for initializing and booting the computer system 100 to run the operating system 162. The BIOS 161 may also include the Advanced Configuration and Power Interface (ACPI) code, which is also known as the “ACPI ASL code.” The BIOS 161 may be implemented on programmable non-volatile memory, for example. In one embodiment, the BIOS 161 includes code for configuring the computer system 100 to perform an ADR of the NVDIMM 120 in the event of a graceful shutdown.

The computer system 100 includes a power supply unit 160 that provides power to the system. The power supply unit 160 generates a POWER_OK signal to indicate that the power supply unit 160 is able to provide adequate power to support the operation of the computer system 100. The POWER_OK signal is withdrawn in the event of a power failure, e.g., brownout, AC power cord removal, malfunction, etc. (FIG. 1, 101). In that case, the OEM logic device 150 detects that the POWER_OK signal indicates a power failure and asserts the PCH ADR_TRIGGER signal in response (FIG. 1, 102). In response to receiving the ADR_TRIGGER signal, the PCH 140 asserts the PM_SYNC signal to allow the CPU 130 to make a data flush and start an ADR timer (FIG. 1, 103). When the ADR timer expires, i.e., times out, the PCH 140 asserts the ADR_COMPLETE signal (FIG. 1, 104) to let the NVDIMM 120 do a SAVE, i.e., transfer contents from the volatile memory 121 to the non-volatile memory 122. The computer system 100 is thus able to perform an ADR cycle to minimize or alleviate the adverse effects of the power failure.

A power failure is an example of a hard shutdown, which is unplanned and is thus not expected by the computer system 100. Hard shutdowns are generally avoided because they can lead to data loss. In marked contrast, a graceful shutdown is an orderly shutdown, which allows the operating system 162 (e.g., MICROSOFT WINDOWS operating system, LINUX operating system) to prepare the computer system 100 (e.g., save data) before the computer system 100 is shut down.

A graceful shutdown may be initiated by invoking the shutdown procedure of the operating system 162. For example, a user may initiate graceful shutdown by selecting system shutdown from a menu provided by the operating system 162. This results in the operating system 162 (e.g., a driver of the operating system 162) being notified of the graceful shutdown. In response, the operating system 162 may call an ACPI_PTS (Prepare to Sleep) function in accordance with ACPI specification to prepare the computer system 100 to go in sleep state. In response, the BIOS 161, which provides the ACPI ASL code support, runs the ACPI_PTS function to prepare the computer system 100 to go to sleep. Thereafter, the operating system 162 writes to the power management control register (PM1_CNT) to configure the computer system 100 to go in the soft off state, which is state S5 in the ACPI specification (PM1_CNT.SLP_TYP to 5, with “5” indicating state S5). The operating system 162 then writes to the power management control register to put the system in the soft off state (PM1_CNT.SLP_EN). Under the ACPI specification, in the soft off state, the computer system 100 powers off all devices and the operating system 162 does not save any context. The computer system 100 thus needs a complete reboot to wake up. The just-described graceful shutdown procedure places the computer system 100 in the soft off state, but does not perform an ADR to save the contents of the volatile memory 121 to the non-volatile memory 122 before going to the soft off state.

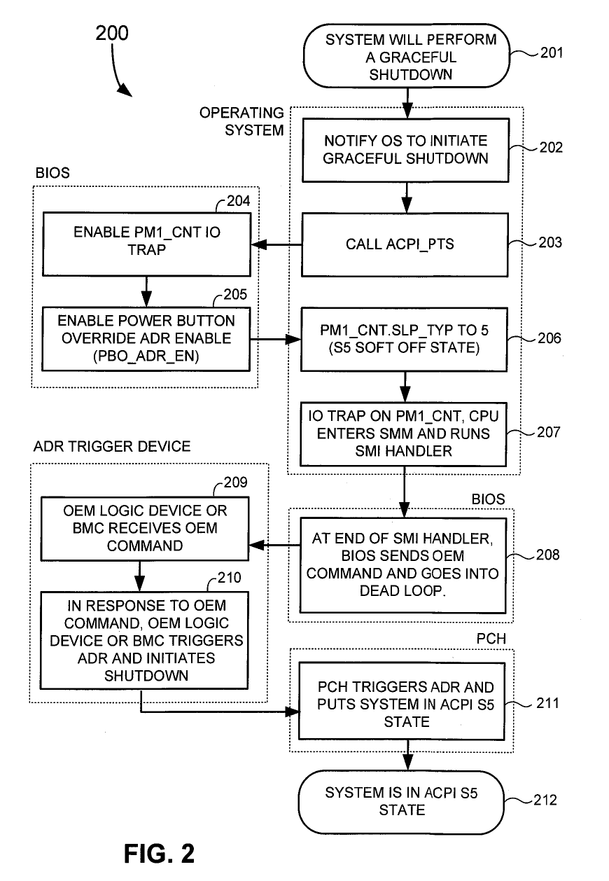

FIG. 2 shows a flow diagram of a method 200 for performing a graceful shutdown of the computer system 100 in accordance with an embodiment of the present invention. As will be more apparent below, the method 200 allows for ADR of an NVDIMM during the graceful shutdown. The method 200 is explained using the components of the computer system 100 for illustration purposes only. As can be appreciated, other components may also be employed without detracting from the merits of the present invention. In the example of FIG. 2, the steps 202, 203, 206, and 207 may be performed by the operating system 162; the steps 204, 205, and 208 may be performed by the BIOS 161; and the step 211 may be performed by the PCH 140.

In one embodiment, the method 200 is a computer-implemented method that is performed when the computer system 100 is to perform a graceful shutdown (FIG. 2, 201). In that case, the operating system 162 is instructed, e.g., by the user, administrator, or a software module, to initiate a graceful shutdown (FIG. 2, 202). In response to receiving the instruction to initiate the graceful shutdown, the operating system 162 prepares the computer system 100 to go to sleep by calling the ACPI prepare to sleep function ACPI_PTS (FIG. 2, 203). The prepare to sleep function may be provided by the BIOS 161, for example.

In one embodiment, the BIOS 161 includes code that enables IO trapping of power management control, such as by enabling PM1_CNT IO trap, where PM1_CNT is a power management control register of the PCH 140 (FIG. 2, 204). This allows trapping of write operations to the power management control register. The BIOS 161 may also include code that assigns a graceful shutdown trigger, which in the example of FIG. 2 is power button activation (FIG. 2, 205). More specifically, the BIOS 161 may enable a power button override ADR enable (PBO_ADR_EN), which enables an ADR to be triggered when the power button is activated. As can be appreciated, the steps 204 and 205 may also be performed by the BIOS 161 during initialization or at any time before configuring the power management control register for soft off state.

The operating system 162 writes to the power management control register to place the computer system 100 in the soft off state, such as by writing 5 (to indicate state S5) to PM1_CNT.SLP_TYP (FIG. 2, 206). As its name implies, the power management control register is a register or other memory location for configuring the power management functions of the computer system 100. Because the power management control register is IO trapped (see FIG. 2, 204) and writing to the power management control register is an IO operation, writing to the power management control register triggers the trap, thereby causing the CPU 130 enter system management mode and run the system management mode interrupt (SMI) handler (FIG. 2, 207). At the end of the SMI handler execution, the BIOS 161 sends an OEM command to the graceful shutdown ADR trigger device (e.g., OEM logic device 150 or BMC 170) and the BIOS 161 goes into a dead loop, i.e., a never ending loop that does not do anything (FIG. 2, 208).

In one embodiment, the OEM command is a unique command that is recognized by the graceful shutdown ADR trigger device to assert the assigned ADR trigger. The graceful shutdown ADR trigger device may be the OEM logic device 150, the BMC 170, or some other device. In response to receiving the OEM command (FIG. 2, 209), the OEM logic device 150 or the BMC 170 will trigger an ADR and initiate shutdown of the computer system 100 (FIG. 2, 210).

In one embodiment, the assigned ADR trigger is power button activation. In that case, in response to receiving the OEM command, the OEM logic device 150 or the BMC 170 triggers an ADR by asserting the power button signal (to simulate power button activation) for a predetermined amount of time to trigger an ADR of the NVDIMM 120. For example, to trigger an ADR, the OEM logic device 150 or the BMC 150 may assert the PWRBTN# pin of the PCH 140 for 4 seconds or longer. In another embodiment, in response to receiving the OEM command, the OEM logic device 150 or the BMC 170 triggers an ADR by asserting the ADR_TRIGGER pin of the PCH 140 and thereafter turn OFF the power to shutdown the computer system 100. Other ways of triggering an ADR may also be performed by the designated graceful shutdown ADR trigger device without detracting from the merits of the present invention.

In response to receiving the ADR trigger, the PCH 140 initiates the ADR to copy the contents of the volatile memory 121 to the non-volatile memory 122 and put the system into ACPI S5 state (FIG. 2, 211). This allows the ADR of the NVDIMM 120 to be performed before the graceful shutdown of the computer system 100 is completed (FIG. 2, 212).

While specific embodiments of the present invention have been provided, it is to be understood that these embodiments are for illustration purposes and not limiting. Many additional embodiments will be apparent to persons of ordinary skill in the art reading this disclosure.

What is claimed is:

1. A method of performing a graceful shutdown of a computer system, the method comprising:
enabling trapping of write operations to a power management control register;
in response to receiving an instruction to perform a graceful shutdown of the computer system, writing to the power management control register to place the computer system in a soft off state;
in response to the writing to the power management control register to place the computer system in the soft off state, entering, by a central processing unit (CPU) of the computer system, a system management mode and running a system management interrupt (SMI) handler;
sending an original equipment manufacturer (OEM) command to assert an asynchronous dynamic random access memory refresh (ADR) trigger; and
in response to receiving the OEM command, asserting the ADR trigger to perform the ADR before completing the graceful shutdown of the computer system,
wherein the ADR transfers contents from a volatile memory of a non-volatile dual in-line memory module (NVDIMM) to a non-volatile memory of the NVDIMM.

2. The method of claim 1, wherein asserting the ADR trigger comprises:
asserting a power button pin of a controller hub.

3. The method of claim 2, wherein the power button pin is asserted for 4 seconds or longer.

4. The method of claim 1, wherein a basic input output system (BIOS) of the computer system enables the trapping of write operations to the power management control register before the instruction to perform the graceful shutdown is received.

5. The method of claim 1, wherein the instruction to perform the graceful shutdown is received from a menu of an operating system of the computer system.

6. The method of claim 1, wherein the OEM command is received by a baseboard management controller (BMC) of the computer system and the BMC asserts the ADR trigger in response to receiving the OEM command.

7. The method of claim 6, wherein the BMC asserts the power button pin of a peripheral controller hub for at least 4 seconds.

8. The method of claim 1, wherein the OEM command is received by an OEM logic device.

9. The method of claim 8, wherein the OEM logic device comprises a programmable logic device.

10. A computer system comprising:
a central processing unit (CPU);
a non-volatile dual in-line memory module (NVDIMM); and
a graceful shutdown asynchronous dynamic random access memory refresh (ADR) trigger device that is configured to assert an ADR trigger to initiate an ADR of the NVDIMM as part of a graceful shutdown of the computer system.

11. The computer system of claim 10, wherein the graceful shutdown ADR trigger device is a baseboard management controller (BMC) of the computer system and the BMC asserts the ADR trigger in response to receiving an original equipment manufacturer (OEM) command.

12. The computer system of claim 11, wherein the ADR trigger is power button activation and the BMC asserts a power button pin of a peripheral controller hub to initiate the ADR of the NVDIMM.

13. The computer system of claim 10, wherein the graceful shutdown ADR trigger device is an OEM logic device and the OEM logic device asserts a power button pin of a peripheral controller hub to initiate the ADR of the NVDIMM.

14. The computer system of claim 10, further comprising:
a basic input output system (BIOS) that sends the OEM command at an end of execution of a system management mode interrupt (SMI) handler.

15. A method of performing a graceful shutdown of a computer system, the method comprising:
receiving an instruction to perform a graceful shutdown of a computer system;
in response to receiving the instruction to perform the graceful shutdown of the computer system, sending a command to an asynchronous dynamic random access memory refresh (ADR) trigger logic device to assert an ADR trigger; and
in response to receiving the command, asserting, by the ADR trigger device, the ADR trigger to initiate an ADR of a non-volatile dual in-line memory module (NVDIMM); and
in response to the ADR trigger being asserted by the ADR trigger device, performing the ADR of the NVDIMM before completing the graceful shutdown of the computer.

16. The method of claim 15, wherein the ADR trigger is power button activation.

17. The method of claim 16, wherein the ADR trigger device is an original equipment manufacturer (OEM) logic device that asserts a power button signal for at least 4 seconds.

18. The method of claim 16, wherein the ADR trigger device is a baseboard management controller (BMC) that asserts a power button signal on a power button pin of a peripheral controller hub.

19. The method of claim 18, wherein the ADR trigger device asserts the power button signal for at least 4 seconds.

20. The method of claim 15, further comprising:
prior to asserting the ADR trigger, placing a central processing unit of the computer in system management mode and sending the command at an end of execution of a system management mode interrupt (SMI) handler.
